(19) United States
(12) Patent Application Publication
(10) Pub. No.: US 2014/0283897 A1
(43) Pub. Date: Sep. 25, 2014

(54) SOLAR POWER MODULE

(71) Applicant: AU OPTRONICS CORPORATION, HSIN-CHU (TW)

(72) Inventors: Yung-Chih CHEN, HSIN-CHU (TW); Huang-Chi TSENG, HSIN-CHU (TW)

(73) Assignee: AU OPTRONICS CORPORATION, HSIN-CHU (TW)

(21) Appl. No.: 14/221,938

(22) Filed: Mar. 21, 2014

(30) Foreign Application Priority Data
Mar. 22, 2013 (CN) 201310094933.7

(51) Int. Cl. H01L 31/042

(52) U.S. Cl. CPC H01L 31/0422
USPC 136/251

(57) ABSTRACT

A solar power module includes a first frame, a second frame, and a solar cell laminate. The first frame includes a first main body and a first clamping portion. The first clamping portion is disposed along the inner edge of the first main body to be ring-shaped. The second frame includes a second main body and a second clamping portion. The second main body abuts against the first main body. The second clamping portion is disposed along the inner edge of the second main body to be ring-shaped and corresponding to the first clamping portion. The periphery of the solar cell laminate is clamped between the first clamping portion and the second clamping portion.

### RELATED APPLICATIONS

This application claims priority to Chinese Application Serial Number 201310094933.7, filed Mar. 22, 2013, which is herein incorporated by reference.

### BACKGROUND

1. Technical Field

The present disclosure relates to a solar power module, and more particularly, to a frame of a solar power module.

2. Description of Related Art

Owing to the shortage of fossil fuels, awareness of the importance of environmental protection is raising. Technologies related to substitute energy resource and green energy have been actively developed in recent years in order to reducing the dependence on fossil fuels and impact of it on the environment. Among the various kinds of technologies of substitute energy resource and green energy, solar cell is on the spotlight. The reason is that the solar cell can directly convert solar energy into electricity, without the generation of carbon dioxide or other harmful substances, such as nitrogen compounds, and the pollution to the environment.

A common solar energy system includes a plurality of solar power modules and an inverter. Each of the solar power modules includes a plurality of solar cells that are connected to each other in series, and each of the solar power modules comprises a junction box for electrical connection. In general, the solar modules can connect to the inverter electrically in a single row or two rows. Further, the frames of the solar power modules are supported by brackets.

However, the conventional frame for the solar module and brackets for supporting have the complicated structures and comprise a large amount of components. The installation of the solar power system needs a lot of workers to do it. Some joints in the brackets only can be completed by welding process in installation so that the cost for construction of solar power system is hard to decrease. Furthermore, the movement of conventional frame and brackets also needs a lot of worker to do it due to many components for brackets. During the movement, the oxidation-resistant layers on surfaces of the frame and the bracket may be even peeled out or scratched, which causes the surfaces of the frame and the bracket vulnerable to corrosion and deformation.

### SUMMARY

In order to solve the problems of the prior art, the disclosure provides an improved solar power module. Particularly, the solar power module includes a first frame, a second frame, and a solar cell laminate member. The first frame includes a first main body and a first clamping portion. The first main body is ring-shaped. The first clamping portion is disposed along the inner edge of the first main body. The second frame includes a second main body and a second clamping portion. The second main body is ring-shaped and abuts against the first main body. The second clamping portion is disposed along the inner edge of the second main body and opposite to the first clamping portion. The periphery of the solar cell laminate member is clamped between the first clamping portion and the second clamping portion.

In an embodiment of the disclosure, the solar cell laminate member is surrounded within the inner edge of the first main body and the inner edge of the second main body.

In an embodiment of the disclosure, the solar power module further includes a glue. The glue is adhered to the first clamping portion, the second clamping portion, and at least a part of the periphery of the solar cell laminate member.

In an embodiment of the disclosure, the first clamping portion has at least one first groove. The first groove is located at a surface of the first clamping portion facing to the second clamping portion. The second clamping portion has at least one second groove. The second groove is located at a surface of the second clamping portion facing to the first clamping portion. The first groove and the second groove form an overflow groove, and a part of the glue is accommodated in the overflow groove.

In an embodiment of the disclosure, at least a part of the periphery of the solar cell laminate member is located in the overflow groove.

In an embodiment of the disclosure, the first groove is formed on the first clamping portion along the inner edge of the first main body, and the second groove is formed on the second clamping portion along the inner edge of the second main body, so as to make the overflow groove be ring-shaped. The periphery of the solar cell laminate member is located in the overflow groove.

In an embodiment of the disclosure, the first groove is adjacent to the junction of the first clamping portion and the first main body. The second groove is adjacent to the junction of the second clamping portion and the second main body.

In an embodiment of the disclosure, the first frame further includes a first stand portion. The first stand portion is disposed at the outer edge of the first main body. The second frame further includes a second stand portion. The second stand portion is disposed at the outer edge of the second main body and opposite to the first stand portion.

In an embodiment of the disclosure, the first stand portion has at least one first screw boss. The second stand portion has at least one second screw boss. The first screw boss lines with the second screw boss.

In an embodiment of the disclosure, the solar power module further includes a screw. The screw is fastened to the first screw boss and the second screw boss.

In an embodiment of the disclosure, the first stand portion further has at least one first outlet hole. The first outlet hole overlaps the first screw boss in the top view. The second stand portion further has at least one second outlet hole. The second outlet hole overlaps the second screw boss in the top view.

In an embodiment of the disclosure, the solar power module further includes a junction box. The junction box includes at least one cable. The cable passes through the first outlet hole and the second outlet hole.

In an embodiment of the disclosure, the first stand portion has two first outlet holes, and the second stand portion has two second outlet holes. Each of the first outlet holes lines with the corresponding second outlet hole. The solar power module further includes a junction box. The junction box includes a cable for connecting positive electrode and a cable for connecting negative electrode. The cable for connecting positive electrode passes through one of the first outlet holes and the corresponding second outlet hole. The cable for connecting negative electrode passes through the other of first outlet holes and the corresponding second outlet hole.

In an embodiment of the disclosure, the second frame has an accommodating space for accommodating the first frame.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is an exploded drawing of a solar power module according to an embodiment of the disclosure;

FIG. 2 is an assembly drawing of the solar power module in FIG. 1;

FIG. 3 is a partial cross-sectional view of the solar power module in FIG. 2 along line 3-3′;

FIG. 4 is a partial cross-sectional view of the solar power module in FIG. 3 along line 4-4′;

FIG. 5 is a partial cross-sectional view according to another embodiment of the disclosure, in which the location of the section is similar to that in FIG. 4;

FIG. 6 is a top view of the solar power module in FIG. 2;

FIG. 7 is a partial sectional view of the solar power module in FIG. 6 along line 7-7′;

FIG. 8 is a rear view of the solar power module in FIG. 1;

FIG. 9 is a top view of a solar power module according to another embodiment of the disclosure;

FIG. 10 is a partial sectional view of the solar power module in FIG. 9 along line 10-10′; and

FIG. 11 is an exploded drawing of a solar power module according to another embodiment of the disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

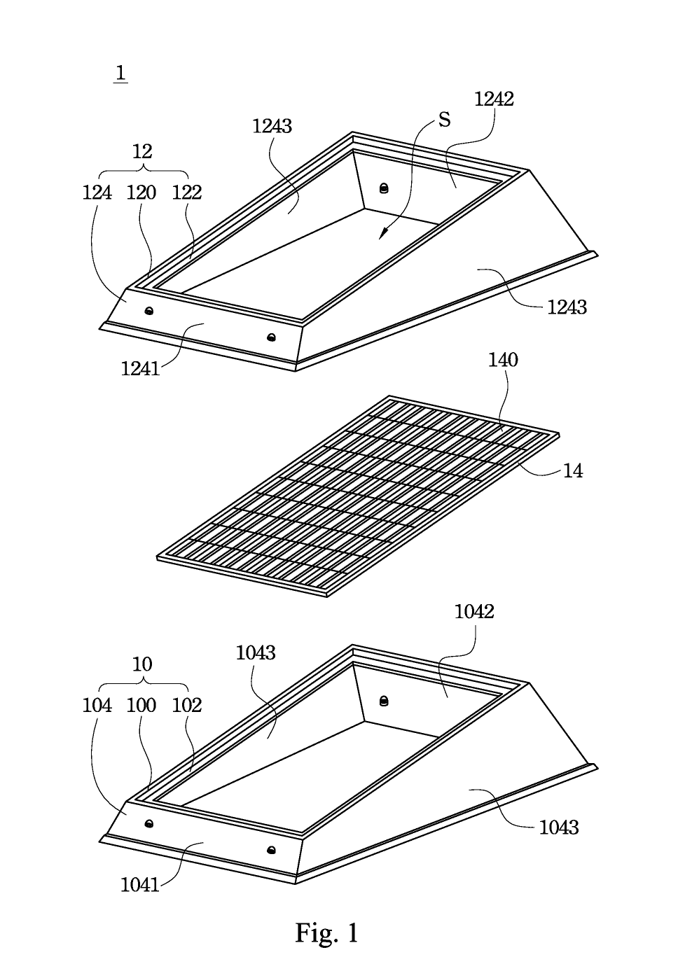

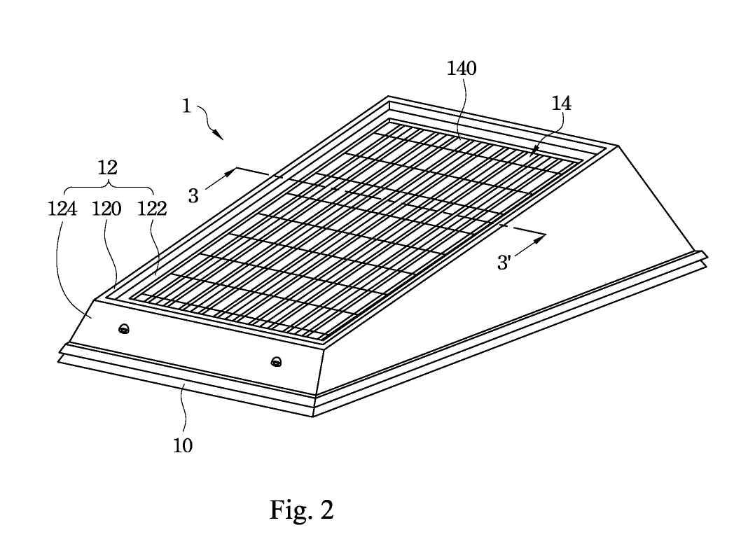

Refer to FIG. 1 and FIG. 2. FIG. 1 is an exploded drawing of a solar power module 1 according to an embodiment of the disclosure. FIG. 2 is an assembly drawing of the solar power module 1 in FIG. 1.

As shown in FIG. 1 and FIG. 2, the solar power module 1 includes a first frame 10, a second frame 12, and a solar cell laminate member 14. In particular, the first frame 10 and the second frame 12 have the same shape and can be stacked one another. The solar cell laminate member 14 is clamped between the first frame 10 and the second frame 12, so as to form the solar power module 1.

The solar cell laminate member 14 of the solar power module 1 can be manufactured by a lamination process (the material can be glass), and the solar cell laminate member 14 includes a plurality of solar cell units 140 laminated therein. The solar cell units 140 of the solar cell laminate member 14 are electrically connected to each other (in series or in parallel) and can absorb sunlight to generate electric current, so as to achieve the purpose of generating electricity. The detailed structures of the first frame 10 and the second frame 12 are described below.

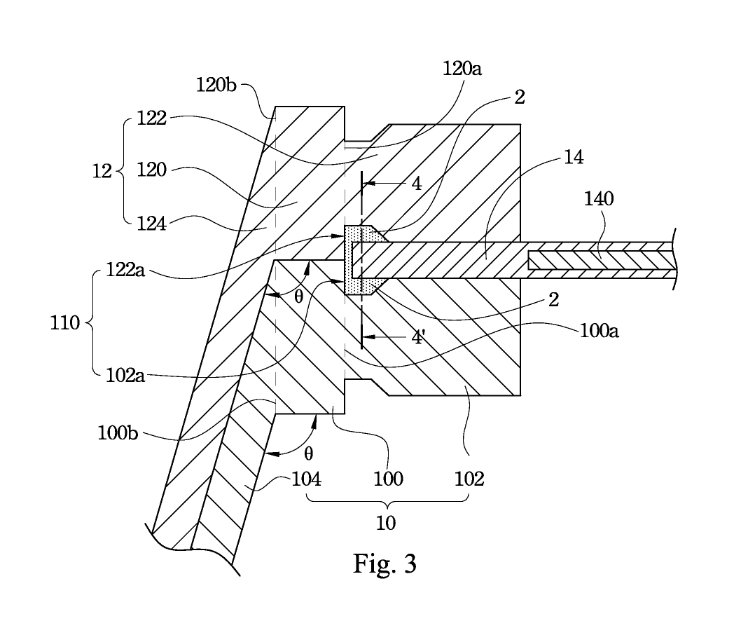

Refer to FIG. 3. FIG. 3 is a partial cross-sectional view of the solar power module 1 in FIG. 2 along line 3-3′.

As shown in FIG. 1 and FIG. 3, the first frame 10 of the solar power module 1 includes a first main body 100 and a first clamping portion 102. The first main body 100 of the first frame 10 is rectangular ring-shaped. The first clamping portion 102 of the first frame 10 is disposed along an inner edge 100a of the first main body 100 to be ring-shaped. The second frame 12 of the solar power module 1 includes a second main body 120 and a second clamping portion 122. The second main body 120 of the second frame 12 is rectangular ring-shaped and abuts on the upper surface of the first main body 100. The second clamping portion 122 of the second frame 12 is disposed along an inner edge 120a of the second main body 120 to be ring-shaped and corresponding to the first clamping portion 102 of the first frame 10.

The contour of the periphery of the solar cell laminate member 14 of the solar power module 1 is similar to the contour of the first main body 100 of the first frame 10 and the contour of the second main body 120 of the second frame 12. When the first frame 10 and the second frame 12 of the solar power module 1 are stacked one another to make the second main body 120 abut on the first main body 100, the solar cell laminate member 14 is surrounded within the inner edge 100a of the first main body 100 and the inner edge 120a of the second main body 120, so as to achieve the purpose of retaining the solar cell laminate member 14.

Moreover, the periphery of the solar cell laminate member 14 of the solar power module 1 is clamped between the first clamping portion 102 and the second clamping portion 122. In the embodiment of the disclosure, the solar cell units 140 in the solar cell laminate member 14 are not overlapped with the first clamping portion 102 of the first frame 10 and the second clamping portion 122 of the second frame 12, so that the overall power efficiency of the solar power module 1 is not affected by the first clamping portion 102 and the second clamping portion 122.

In the embodiment of the disclosure, the solar power module further includes glue 2. The glue 2 is adapted for adhering the first clamping portion 102 of the first frame 10, the second clamping portion 122 of the second frame 12, and at least a part of the periphery of the solar cell laminate member 14. By using the glue 2 to fixing the solar cell laminate member 14 between the first frame 10 and the second frame 12, the solar power module 1 not only can rapidly fix the solar cell laminate member 14 but also can save the costs of installation.

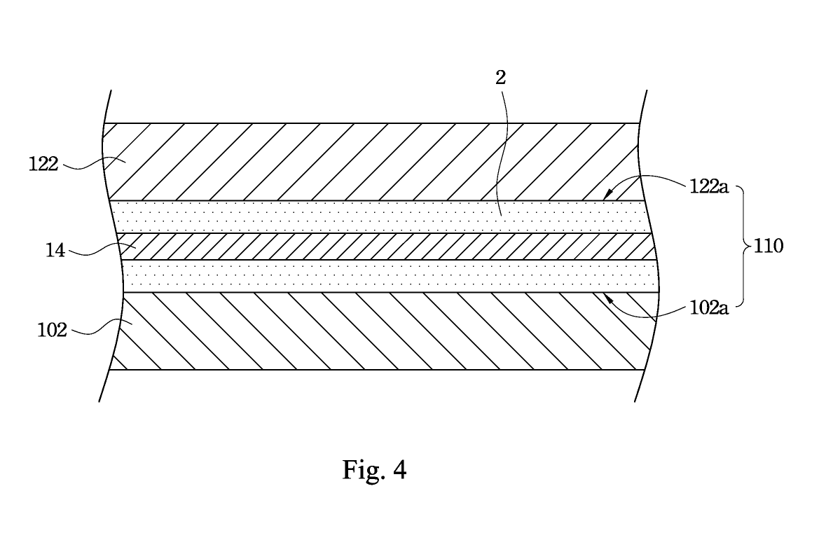

Refer to FIG. 4. FIG. 4 is a partial cross-sectional view of the solar power module 1 in FIG. 3 along line 4-4′.

As shown in FIG. 3 and FIG. 4, the first clamping portion 102 of the first frame 10 has two opposite first grooves 102a respectively located at the upper surface and the lower surface of the first clamping portion 102 adjacent to the inner edge 100a of the first main body 100. The second clamping portion 122 of the second frame 12 has two opposite second grooves 122a respectively located at the upper surface and the lower surface of the second clamping portion 122 adjacent to the inner edge 120a of the second main body 120. The first groove 102a on the upper surface of the first clamping portion 102 faces to the second groove 122a on the lower surface of the second clamping portion 122. When the first frame 10 and the second frame 12 of the solar power module 1 are stacked one another to make the second main body 120 abut on the first main body 100, the first groove 102a of the first clamping portion 102 and the second groove 122a of the second clamping portion 122 form an overflow groove 110. When the glue 2 is adhered to the solar cell laminate member 14 between the first clamping portion 102 of the first frame 10 and the second clamping portion 122 of the second frame 12, a part of the glue 2 flows to be accommodated in the overflow groove 110.

Furthermore, the first grooves 102a are adjacent to the junction of the first clamping portion 102 and the first main body 100, and the second grooves 122a are adjacent to the junction of the second clamping portion 122 and the second main body 120, but the disclosure is not limited in this regard.

In the embodiment of the disclosure, the first groove 102a is formed on the first clamping portion 102 along the inner edge 100a of the first main body 100, and the second groove 122a is formed on the second clamping portion 122 along the inner edge 120a of the second main body 120, so as to make the overflow groove 110 be ring-shaped. Accordingly, the whole periphery of the solar cell laminate member 14 is clamped between the first clamping portion 102 and the second clamping portion 122 and is accommodated in the overflow groove 110. However, the shape of the first groove 102a of the first clamping portion 102, the shape of the second groove 122a of the second clamping portion 122, and the shape of the overflow groove 110 are not limited by the embodiment.

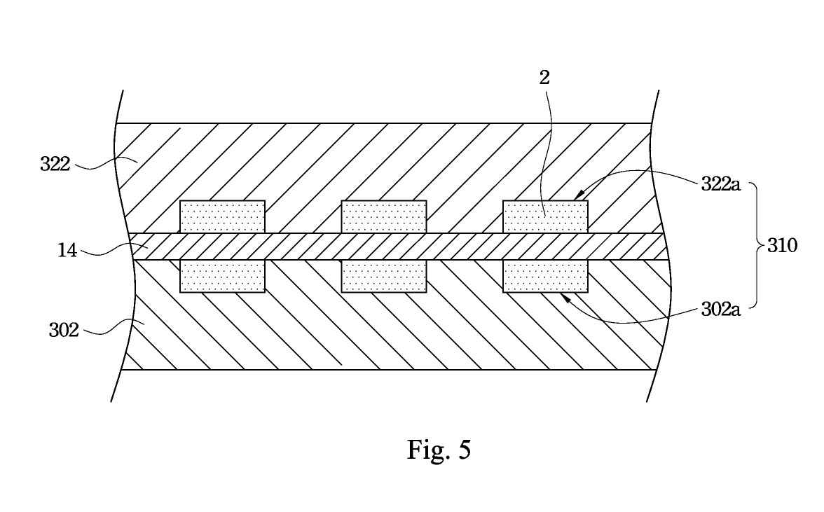

Refer to FIG. 5. FIG. 5 is a partial cross-sectional view according to another embodiment of the disclosure, in which the location of the section is similar to that in FIG. 4.

As shown in FIG. 3 and FIG. 5, both the upper surface and the lower surface of the first clamping portion 302 have plurality of first grooves 302a, and both the upper surface and the lower surface of the second clamping portion 322 have plurality of second grooves 322a. Each of the first grooves 302a on the upper surface of the first clamping portion 302 faces to and is aligned with the corresponding one of the second groove 322a on the lower surface of the second clamping portion 322. Accordingly, the first grooves 302a on the upper surface of the first clamping portion 302 and the second grooves 322a on the lower surface of the second clamping portion 322 form a plurality of overflow grooves 310. When the glue 2 is adhered to the solar cell laminate member 14 between the first clamping portion 302 and the second clamping portion 322, parts of the glue 2 flows and is accommodated in the overflow grooves 310.

Furthermore, the sections of the first grooves 302a are separately formed on the first clamping portion 302 and line along the junction of the first clamping portion 302 and the first main body 100. The sections of the second grooves 322a are separately formed on the second clamping portion 322 and line along the junction of the second clamping portion 322 and the second main body 120. Accordingly, when the solar cell laminate member 14 is clamped between the first clamping portion 302 and the second clamping portion 322, parts of the periphery of the solar cell laminate member 14 are located in the overflow grooves 310.

Compared with the embodiment in the FIG. 4, the sections of the first grooves 302a on the first clamping portion 302 and the sections of the second grooves 322a on the second clamping portion 322 of the embodiment separately form plural recesses, rather than an integral ring-shaped recessed structure. Therefore, the first clamping portion 302 and the second clamping portion 322 of the embodiment have better structural strengths.

Compared with the embodiment in the FIG. 4, the total space capacity of the separate overflow grooves 310 is smaller. Therefore, less amount of glue 2 to adhere the solar cell laminate member 14 is needed in this embodiment.

As shown in FIG. 3, the first frame 10 of the solar power module 1 further includes a first stand portion 104. The first stand portion 104 of the first frame 10 is disposed at the outer edge 100b of the first main body 100. An angle θ is included between the first stand portion 104 and the first main body 100, which is preferably an obtuse angle, for example in a range of about 100 to about 150 degrees. The second frame 12 of the solar power module 1 further includes a second stand portion 124. The second stand portion 124 of the second frame 12 is disposed at the outer edge 120b of the second main body 120 and corresponding to the first stand portion 104. Similarly, an angle θ is included between the second stand portion 124 and the second main body 120, which is preferably an obtuse angle, for example in a range of about 100 to about 150 degrees.

In particular, as shown in FIG. 1, the first stand portion 104 of the first frame 10 extends outwardly and downwardly from the outer edge 100b of the first main body 100. The first stand portion 104 includes a plurality of sub-stands, for example, a first sub-stand 1041, a second sub-stand 1042, and two third sub-stands 1043. The first sub-stand 1041 and the second sub-stand 1042 are respectively connected to the two opposite outer edges of the first main body 100 and the third sub-stands 1043 are respectively connected between the first sub-stand 1041 and the second sub-stand 1042. Similarly, the second stand portion 124 of the second frame 12 extends outwardly and downwardly from the outer edge 120b of the second main body 120. The second stand portion 124 includes a plurality of sub-stands, for example, a fourth sub-stand 1241, a fifth sub-stand 1242, and two sixth sub-stands 1243. The fourth sub-stand 1241 and the fifth sub-stand 1242 are respectively connected to the two opposite outer edges of the second main body 120 and the sixth sub-stands 1243 are respectively connected between the fourth sub-stand 1241 and the fifth sub-stand 1242. Accordingly, when the first frame 10 and the second frame 12 of the solar power module 1 are stacked one another to make the second main body 120 abut on the first main body 100 (as shown in FIG. 2 and FIG. 3), the first stand portion 104 of the first frame 10 and the second stand portion 124 of the second frame 12 do not interfere with each other. On the contrary, the first frame 10 is located in the accommodating space S of the second frame 12, and the first stand portion 104 of the first frame 10 and the second stand portion 124 of the second frame 12 are stacked and abutted against each other.

In an embodiment of the disclosure, the first frame 10 and the second frame 12 are stacked and placed on a horizontal plane. When the gravity force direction is defined to be 0 degree, an inclined angle by which the first stand portion 104 of the first frame 10 is inclined relative to the outer edge 100b of the first main body 100, and the inclined angle by which the second stand portion 124 of the second frame 12 is inclined relative to the outer edge 120b of the second main body 120 are both within the range of 10˜60 degrees. However, the disclosure is not limited in this regard.

As shown in FIG. 1, a length of the first sub-stand 1041 of the first stand portion 104 at the front side of the first frame 10 is different from a length of the second sub-stand 1042 of the first stand portion 104 at the rear side of the first frame 10, for example, the length of the first sub-stand 1041 is smaller than the length of the second sub-stand 1042. A length of the fourth sub-stand 1241 of the second stand portion 124 at the front side of the second frame 12 is different from a length of the fifth sub-stand 1242 of the second stand portion 124 at the rear side of the second frame 12, for example, the length of the fourth sub-stand 1241 is smaller than the length of the fifth sub-stand 1242. Hence, the inclined design of the solar power module 1 of the embodiment that makes the solar cell laminate member 14 be inclined relative to the ground has the advantage of effectively utilizing sunlight.

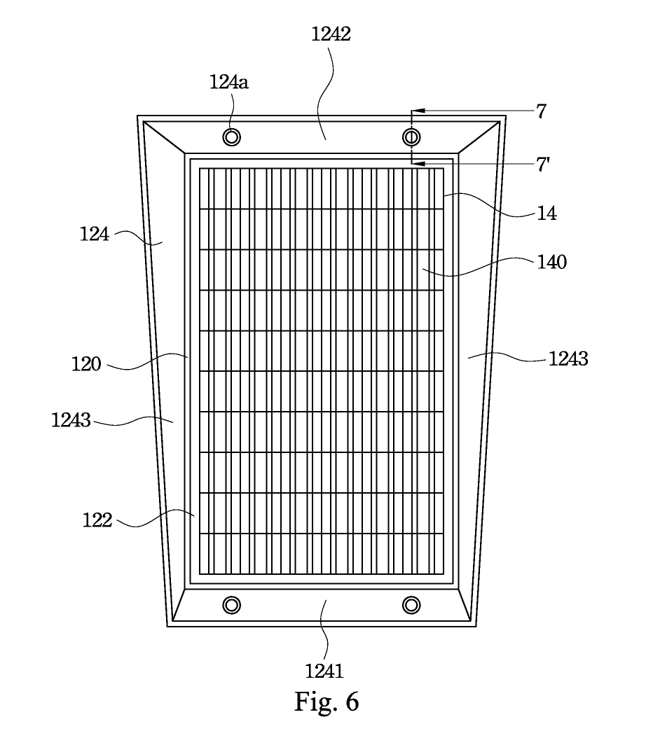

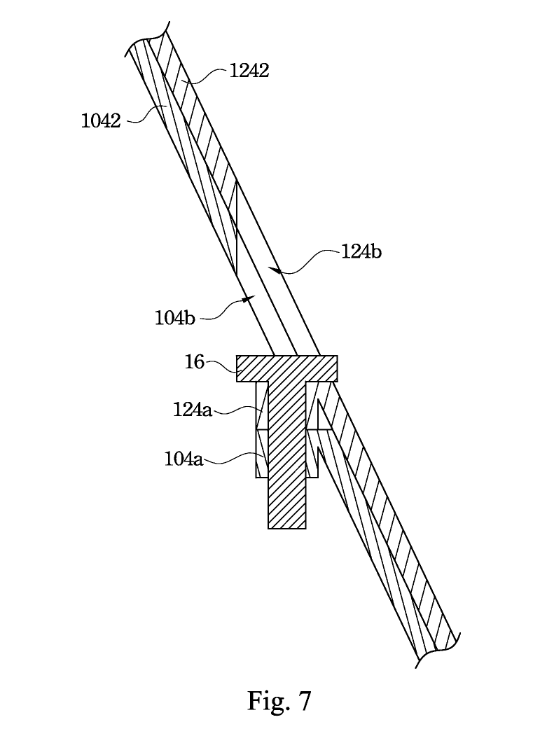

Refer to FIG. 6 and FIG. 7. FIG. 6 is a top view of the solar power module 1 in FIG. 2. FIG. 7 is a partial cross-sectional view of the solar power module 1 in FIG. 6 along line 7-7′.

As shown in FIG. 6 and FIG. 7, the first sub-stand 1041 and the second sub-stand 1042 of the first stand portion 104 of the first frame 10 each has a plurality of first screw bosses 104a. The fourth sub-stand 1241 and the fifth sub-stand 1242 of the second stand portion 124 of the second frame 12 each has a plurality of second screw bosses 124a. The first screw bosses 104a of the second sub-stand 1042 of the first stand portion 104 are disposed at the inner side of the first stand portion 104, and the second screw bosses 124a of the fifth sub-stand 1242 of the second stand portion 124 are disposed at the inner side of the second stand portion 124. When the first frame 10 and the second frame 12 of the solar power module 1 are stacked and the second main body 120 abuts against the first main body 100, the first screw bosses 104a connect and align with the second screw bosses 124a, as shown in FIG. 7.

Furthermore, the solar power module 1 further includes screws 16. Each of the screws 16 is fastened to the first screw boss 104a and the corresponding second screw boss 124a, so as to increase the fixing strength between the first frame 10 and the second frame 12.

As shown in FIG. 7, each of the first sub-stand 1041 and the second sub-stand 1042 of the first stand portion 104 of the first frame 10 further has a plurality of first outlet holes 104b. The first outlet holes 104b of the first stand portion 104 are adjacent to and connect the first screw bosses 104a, respectively. Each of the fourth sub-stand 1241 and the fifth sub-stand 1242 of the second stand portion 124 of the second frame 12 further has a plurality of second outlet holes 124b. The second outlet holes 124b of the second stand portion 124 are adjacent to and connect the second screw bosses 124a, respectively.

Furthermore, the first outlet holes 104b through the first stand portion 104 are formed along the fastening direction (i.e., the vertical direction in FIG. 7), and the first screw bosses 104a and the first outlet holes 104b are overlapped in the top view, respectively. Similarly, the second outlet holes 124b through the second stand portion 124 are formed along the fastening direction, and the second screw bosses 124a and the second outlet holes 124b are overlapped in the top view, respectively.

Accordingly, each of the screws 16 of the solar power module 1 can sequentially passes through the corresponding second outlet hole 124b of the second stand portion 124 and the corresponding first outlet hole 104b of the first stand portion 104, and then be sequentially fastened to the corresponding second screw boss 124a of the second stand portion 124 and the corresponding first screw boss 104a of the first stand portion 104 along the fastening direction.

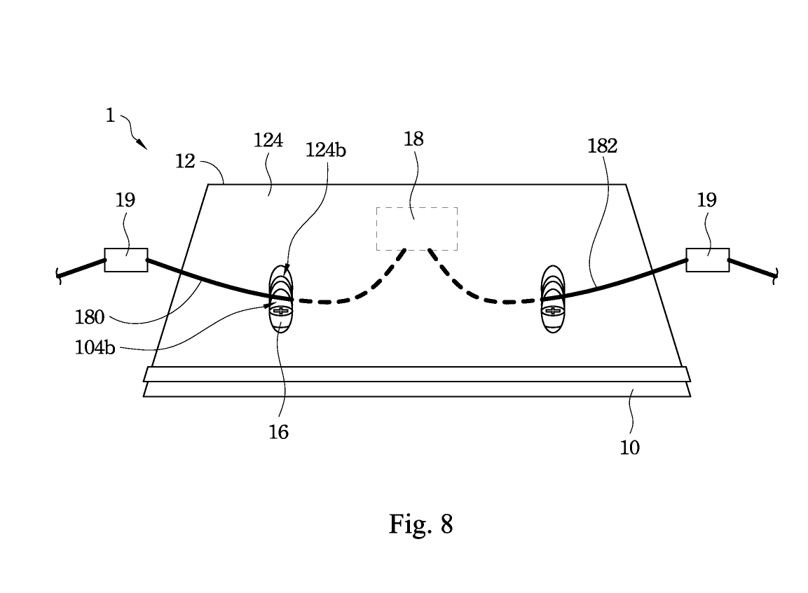

Refer to FIG. 8. FIG. 8 is a rear view of the solar power module 1 in FIG. 1.

As shown in FIG. 8, the first stand portion 104 of the first frame 10 has two first outlet holes 104b located at the rear side of the first stand portion 104, the second stand portion 124 of the second frame 12 has two second outlet holes 124b located at the rear side of the second stand portion 124, and each of the first outlet holes 104b is communicated with the corresponding second outlet hole 124b.

The solar power module 1 further includes a junction box 18. The junction box 18 of the solar power module 1 is disposed at the interior of the first frame 10 and the second frame 12 and includes a positive electrode cable 180 and a negative electrode cable 182. The cable 180 for connecting positive electrode of the junction box 18 passes through one of the first outlet holes 104b and the corresponding second outlet hole 124b (i.e., the left first outlet hole 104b and the left second outlet hole 124b in FIG. 8). The cable 182 for negative electrode of the junction box 18 passes through another of first outlet holes 104b and the corresponding second outlet hole 124b (i.e., the right first outlet hole 104b and the right second outlet hole 124b in FIG. 8).

In general, an outdoor solar power system includes a plurality of the solar power modules 1 that are disposed side by side and electrically connected to each other. The solar power system further includes a plurality of connectors 19. As shown in FIG. 8, the connector 19 on the left side links the cable 180 for connecting positive electrode of the junction box 18 and the cable 182 for connecting negative electrode of another junction box (not shown) on another left solar power module (not shown). The connector 19 on the right side links the cable 182 for connecting negative electrode of the junction box 18 and the cable 180 for connecting positive electrode of another junction box (not shown) on another right solar power module (not shown). Therefore, the solar power modules 1 included in the solar power system can be electrically connected to each other under this construction.

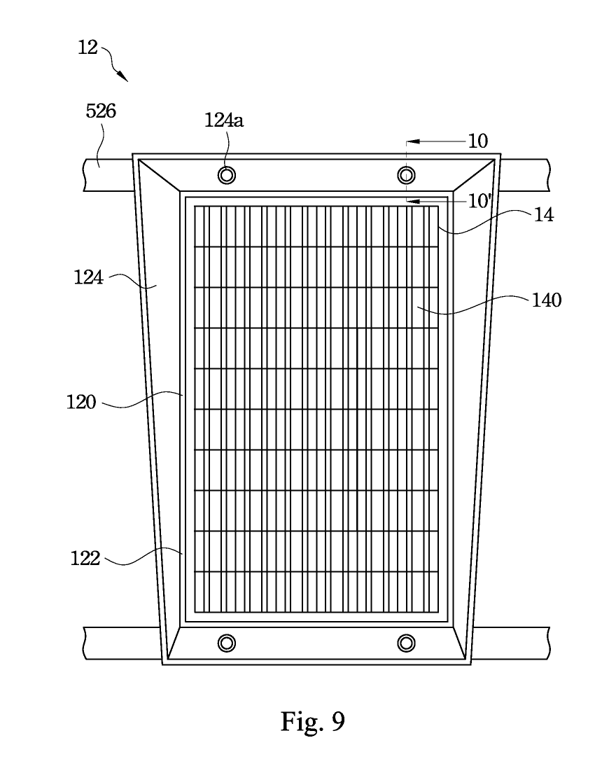

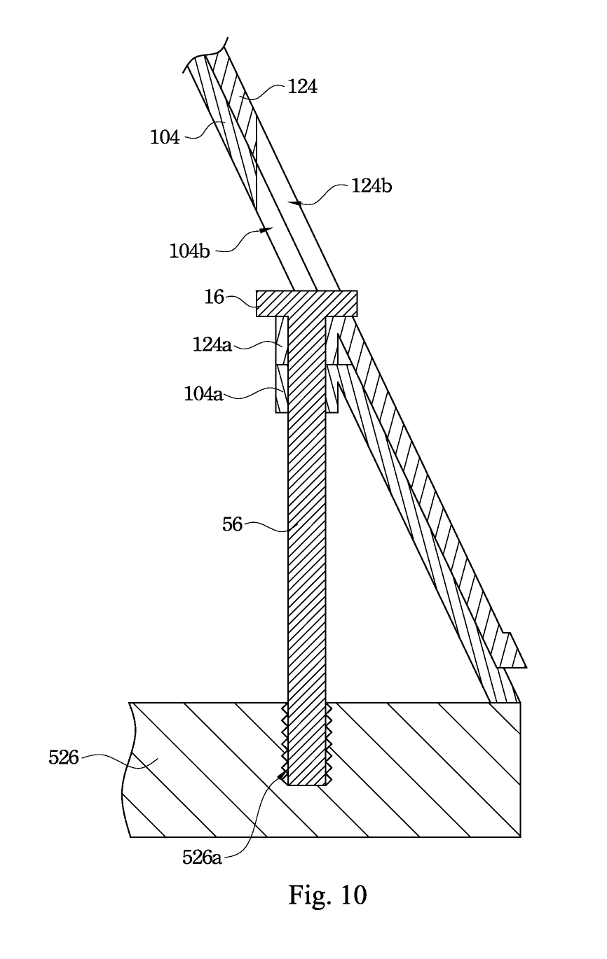

Refer to FIG. 9 and FIG. 10. FIG. 9 is a top view of a solar power system according to another embodiment of the disclosure. FIG. 10 is a partial cross-sectional view of the solar power system in FIG. 9 along line 10-10′.

As shown in FIG. 9 and FIG. 10, the solar power system includes two brackets 526. The brackets 526 of the solar power system are disposed under the first frame 10 of the solar power module 1 and abut against the first stand portion 104 (as shown in FIG. 10). Each of the brackets 526 has a plurality of screw holes 526a, and each of the screw holes 526a is located right under the corresponding second screw boss 124a of the second stand portion 124 and the corresponding first screw boss 104a of the first stand portion 104. Therefore, after respectively passing through the first screw bosses 104a and the second screw bosses 124a, the screws 56 can be further respectively fastened to the screw holes 526a of the brackets 526, so as to fix the first frame 10 and the second frame 12 on the brackets 526. By fastening the solar power modules 1 to the brackets 526, the overall structural strength of the solar power system can be improved. Even in the severe external environment (e.g., natural disasters such as typhoons), the solar power modules 1 included in the solar power system can still be on the brackets 526 stably.

As shown in FIG. 1, the first stand portion 104 of the first frame 10 is disposed along the outer edge 100b of the first main body 100 to be ring-shaped, and the second stand portion 124 of the second frame 12 is disposed along the outer edge 120b of the second main body 120 to be ring-shaped. Therefore, the solar power module 1 has enough supporting force at the bottom to bear a weight of the solar power module 1, but the disclosure is not limited in this regard.

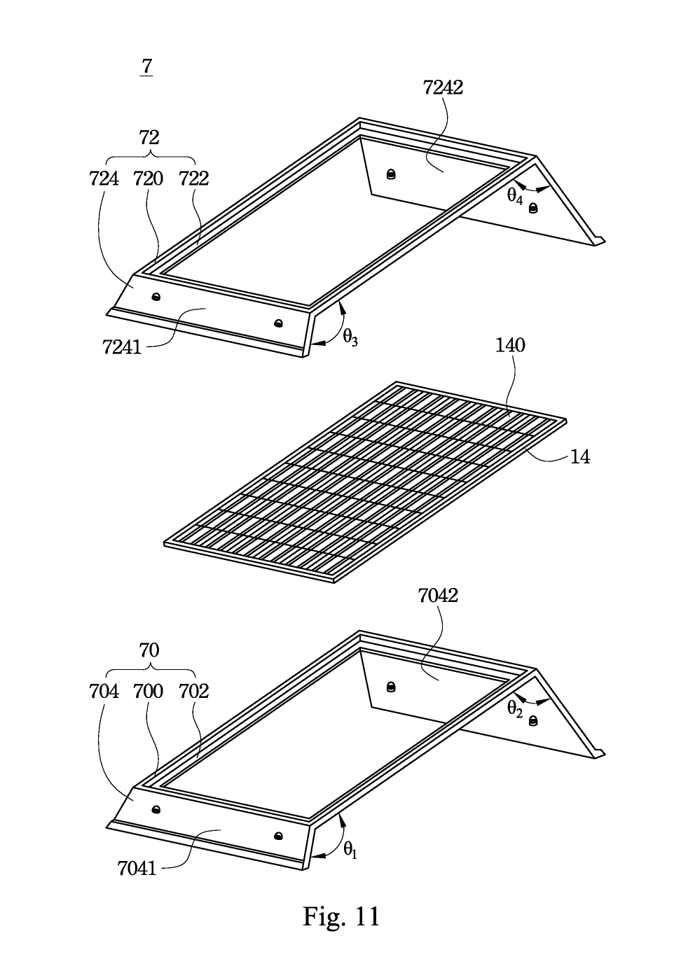

Refer to FIG. 11. FIG. 11 is an exploded drawing of a solar power module 7 according to another embodiment of the disclosure.

As shown in FIG. 11, this embodiment is under the condition that the new structure does not decrease the overall strength of the solar power module 7. The first main body 700 and the first clamping portion 702 of the first frame 70 are respectively similar to that of the first frame 10 in FIG. 1, but the first stand portion 704 of the first frame 70 is discontinuously disposed at the partial outer edge of the first main body 700 (e.g., the front edge and the rear edge of the first main body 700). For example, the first stand portion 704 merely includes a first sub-stand 7041 and a second sub-stand 7042, a length of the first sub-stand 7041 is smaller than a length of the second sub-stand 7042. The first main body 700 and the first sub-stand 7041 include an included angle θ₁ therebetween while the first main body 700 and the second sub-stand 7042 include an included angle θ₂ therebetween, in which θ₁>θ₂. Similarly, the second main body 720 and the second clamping portion 722 of the second frame 72 are respectively similar to that of the second frame 12 in FIG. 1, but the second stand portion 724 of the second frame 72 is discontinuously disposed at the partial outer edge of the second main body 720 (e.g., the front edge and the rear edge of the second main body 720). For example, the second stand portion 724 merely includes a third sub-stand 7241 and a fourth sub-stand 7242, a length of the third sub-stand 7241 is smaller than a length of the fourth sub-stand 7242. The second main body 720 and the third sub-stand 7241 include an included angle θ₃ therebetween while the second main body 720 and the fourth sub-stand 7242 include an included angle θ₄ therebetween, in which θ₃>θ₄. Hence, the costs of material for the solar power module 7 can be saved.

According to the foregoing recitations of the embodiments of the disclosure, it can be seen that the solar power module of the disclosure includes two frames having the same shape, and these frames can be stacked one another, so as to clamp a solar cell laminate member therebetween to complete the assembly of the solar power module. Because the frames have the same structure, they can be produced by the same mode. It means the different modes for upper and lower frame is unnecessary and the cost of mode developing can be reduced. During the assembly processes of the solar power module, glue can be further used to adhere the solar cell laminate member between the frames. It not only can fix the solar cell laminate member quickly and tightly but also can save the costs in assembling process comparing to conventional one. Furthermore, because the solar power modules have the same shape, the solar power modules can also be stacked to save space for store and reduce the amount of workers during packaging and transporting.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A solar power module comprising:
a first frame comprising:
a first main body being ring-shaped; and
a first clamping portion disposed along an inner edge of the first main body;
a second frame comprising:
a second main body being ring-shaped and abutting on the first main body; and
a second clamping portion disposed along an inner edge of the second main body and corresponding to the first clamping portion; and
a solar cell laminate member, a periphery of the solar cell laminate member being clamped between the first clamping portion and the second clamping portion.

2. The solar power module of claim 1, wherein the solar cell laminate member is surrounded within the inner edge of the first main body and the inner edge of the second main body.

3. The solar power module of claim 1, further comprising:
a glue adhered to the first clamping portion, the second clamping portion, and at least a part of the periphery of the solar cell laminate member.

4. The solar power module of claim 3, wherein the first clamping portion has at least one first groove, the first groove is located at a surface of the first clamping portion facing to the second clamping portion, the second clamping portion has at least one second groove, the second groove is located at a surface of the second clamping portion facing to the first clamping portion, the first groove and the second groove form an overflow groove, and a part of the glue is accommodated in the overflow groove.

5. The solar power module of claim 4, wherein at least a part of the periphery of the solar cell laminate member is located in the overflow groove.

6. The solar power module of claim 4, wherein the first groove is formed on the first clamping portion along the inner edge of the first main body, and the second groove is formed on the second clamping portion along the inner edge of the second main body, so as to make the overflow groove be ring-shaped, and the periphery of the solar cell laminate member is located in the overflow groove.

7. The solar power module of claim 4, wherein the first groove is adjacent to a junction of the first clamping portion and the first main body, and the second groove is adjacent to a junction of the second clamping portion and the second main body.

8. The solar power module of claim 1, wherein the first frame further comprises a first stand portion disposed at an outer edge of the first main body, and the second frame further comprises a second stand portion disposed at an outer edge of the second main body and is corresponding to the first stand portion.

9. The solar power module of claim 8, wherein the first stand portion has at least one first screw boss, the second stand portion has at least one second screw boss, and the first screw boss is communicated with the second screw boss.

10. The solar power module of claim 9, further comprising:
a screw fastened to the first screw boss and the second screw boss.

11. The solar power module of claim 9, wherein the first stand portion further has at least one first outlet hole, the first outlet hole overlaps the first screw boss in the top view, the second stand portion further has at least one second outlet hole, and the second outlet hole overlap the second screw boss in the top view.

12. The solar power module of claim 11, further comprising a junction box, the junction box comprising at least one cable, and the cable passing through the first outlet hole and the second outlet hole.

13. The solar power module of claim 8, wherein the first stand portion has two first outlet holes, the second stand portion has two second outlet holes, each of the first outlet holes aligns with the corresponding second outlet hole, the solar power module further comprises a junction box, the junction box comprises a cable for connecting positive electrode and a cable for connecting negative electrode, the cable for connecting positive electrode passes through one of the first outlet holes and the corresponding second outlet hole, and the cable for connecting negative electrode passes through the other of first outlet holes and the corresponding second outlet hole.

14. The solar power module of claim 8, wherein the second frame has an accommodating space for accommodating the first frame.

15. The solar power module of claim 8, wherein the first stand portion comprises a plurality of sub-stand, an obtuse angle is included between each sub-stand and the first main body.

16. The solar power module of claim 8, wherein the first stand portion comprises a first sub-stand and a second sub-stand, the first sub-stand and the second sub-stand are respectively connected to the opposite two outer edges of the first main body and have different lengths.

17. The solar power module of claim 16, wherein a length of the first sub-stand is smaller then a length of the second sub-stand, a first obtuse angle is included between the first sub-stand and the first main body, and a second obtuse angle is included between the second sub-stand and the first main body, wherein the first obtuse angle is greater than the second obtuse angle.

18. The solar power module of claim 8, wherein the second stand portion comprises a plurality of sub-stand, an obtuse angle is included between each sub-stand and the second main body.

19. The solar power module of claim 8, wherein the second stand portion comprises a third sub-stand and a fourth sub-stand, the third sub-stand and the fourth sub-stand are respectively connected to the opposite two outer edges of the second main body and have different lengths.

20. The solar power module of claim 19, wherein a length of the third sub-stand is smaller then a length of the fourth sub-stand, a third obtuse angle is included between the third sub-stand and the second main body, and a fourth obtuse angle is included between the fourth sub-stand and the second main body, wherein the third obtuse angle is greater than the fourth obtuse angle.
